(19) United States
(12) Patent Application Publication
(10) Pub. No.: US 2017/0023616 A1
(43) Pub. Date: Jan. 26, 2017

(54) INTERDIGITIZED POLYSYMMETRIC FANOUTS, AND ASSOCIATED SYSTEMS AND METHODS

(71) Applicant: Translarity, Inc., Fremont, CA (US)

(72) Inventor: Morgan T. Johnson, Beaverton, OR (US)

(73) Assignee: Translarity, Inc., Fremont, CA (US)

(21) Appl. No.: 15/167,004

(22) Filed: May 27, 2016

Related U.S. Application Data
(60) Provisional application No. 62/230,608, filed on Jun. 10, 2015.
(60) Provisional application No. 62/255,230, filed on Nov. 13, 2015.

(51) Int. Cl. G01R 1/073; H01L 23/00; G01R 31/28; H01L 21/683

(52) U.S. Cl. CPC G01R 1/07378; H01L 21/6838; H01L 24/06; G01R 31/2889

(57) ABSTRACT

Systems and methods for testing semiconductor wafers using a wafer translator are disclosed herein. In one embodiment, an apparatus for testing semiconductor dies includes a wafer translator having a wafer-side facing the dies and an inquiry-side facing away from the wafer-side. The inquiry-side of the wafer translator carries a first and a second plurality of inquiry-side contact structures. The first plurality of the inquiry-side contact structures is interleaved with the second plurality of the inquiry-side contact structures.

### CROSS-REFERENCES TO RELATED APPLICATIONS

This application claims the benefit of U.S. Provisional Application No. 62/230,608, filed Jun. 10, 2015, and U.S. Provisional Application No. 62/255,230, filed Nov. 13, 2015, both of which are hereby incorporated by reference in their entireties.

### FIELD OF THE INVENTION

The present invention relates generally to semiconductor test equipment, and more particularly relates to methods and apparatus for routing test signals/power to and from integrated circuits of semiconductor dies.

### BACKGROUND

Integrated circuits are used in a wide variety of products. Integrated circuits have continuously decreased in price and increased in performance, becoming ubiquitous in modern electronic devices. These improvements in the performance/cost ratio are based, at least in part, on miniaturization, which enables more semiconductor dies to be produced from a wafer with each new generation of the integrated circuit manufacturing technology. Furthermore, the total number of the signal and power/ground contacts on a semiconductor die generally increases with new, more complex die designs.

Prior to shipping a semiconductor die to a customer, the performance of the integrated circuits is tested, either on a statistical sample basis or by testing each die. An electrical test of the semiconductor die typically includes powering the die through the power/ground contacts, transmitting signals to the input contacts of the die, and measuring the resulting signals at the output contacts of the die. Therefore, during the electrical test at least some contacts on the die must be electrically contacted to connect the die to sources of power and test signals.

Conventional test contactors include an array of contact pins attached to a substrate that can be a relatively stiff printed circuit board (PCB). In operation, the test contactor is pressed against a wafer such that the array of contact pins makes electrical contact with the corresponding array of die contacts (e.g., pads or solderballs) on the dies (i.e., devices under test or DUTs) of the wafer. Next, a wafer tester sends electrical test sequences (e.g., test vectors) through the test contactor to the input contacts of the dies of the wafer. In response to the test sequences, the integrated circuits of the tested die produce output signals that are routed through the test contactor back to the wafer tester for analysis and determination whether a particular die passes the test. Next, the test contactor is stepped onto another die or group of dies that are tested in parallel to continue testing till the entire wafer is tested. If, for example, the test contactor contacts a group of dies that is tested in parallel, then to test some groups of the dies that are close to the edge of the wafer, the test contactor must step over the edge of the wafer. For example, if all the dies on the wafer are to be tested in four touch-downs, then the test contactor may contact a quarter of the wafer in one touch-down, and, after testing the dies in that segment of the wafer, move into the contact with another quarter of the wafer in the next touch-down, and so on. Such a sequence of contacts between the test contactor and the wafer may result in an overhang of the test contactor over the edge of the wafer. The overhang may damage some conventional contactors because of an uneven force loading of the contactor when not engaging all their contact pins against the dies under the test.

In general, an increasing number of die contacts that are distributed over a decreasing area of the die results in smaller contacts spaced apart by smaller distances (e.g., a smaller pitch). Furthermore, a characteristic diameter of the contact pins of the test contactor generally scales with a characteristic dimension of the contact structures on the semiconductor die or the package. Therefore, as the contact structures on the die become smaller and/or have a smaller pitch, the contact pins of the test contactors become smaller, too. However, it is difficult to significantly reduce the diameter and pitch of the contact pins of the test contactor, e.g., because of the difficulties in machining and assembling such small parts, resulting in low yield and inconsistent performance from one test contactor to another. Furthermore, precise alignment between the test contactor and the wafer is difficult because of the relatively small size/pitch of the contact structures on the wafer.

Accordingly, there remains a need for cost effective test contactors that are not damaged by uneven loading and that can scale down in size with the size and pitch of the contact structure on the die.

### BRIEF DESCRIPTION OF THE DRAWINGS

The foregoing aspects and many of the attendant advantages of this invention will become more readily appreciated with reference to the following detailed description, when taken in conjunction with the accompanying drawings, wherein:

FIG. 1A is an exploded view of a portion of a test stack for testing semiconductor wafers in accordance with an embodiment of the presently disclosed technology.

FIG. 1B is a partially schematic, top view of a wafer translator configured in accordance with an embodiment of the presently disclosed technology.

FIG. 1C is a partially schematic, bottom view of a wafer translator configured in accordance with an embodiment of the presently disclosed technology.

FIG. 2 is a partially schematic top view of an assembly of a wafer translator and a wafer in accordance with an embodiment of the presently disclosed technology.

FIG. 2A is a detail view of the assembly illustrated in FIG. 2.

FIG. 3 is a partially schematic view of routing of a wafer translator in accordance with an embodiment of the presently disclosed technology.

FIGS. 4A-4D are partially schematic views of a wafer translator routing in accordance with an embodiment of the presently disclosed technology.

FIG. 5 is a partially schematic view of a wafer translator routing in accordance with an embodiment of the presently disclosed technology.

FIG. 6 is a partially schematic view of a wafer translator routing in accordance with another embodiment of the presently disclosed technology.

### DETAILED DESCRIPTION

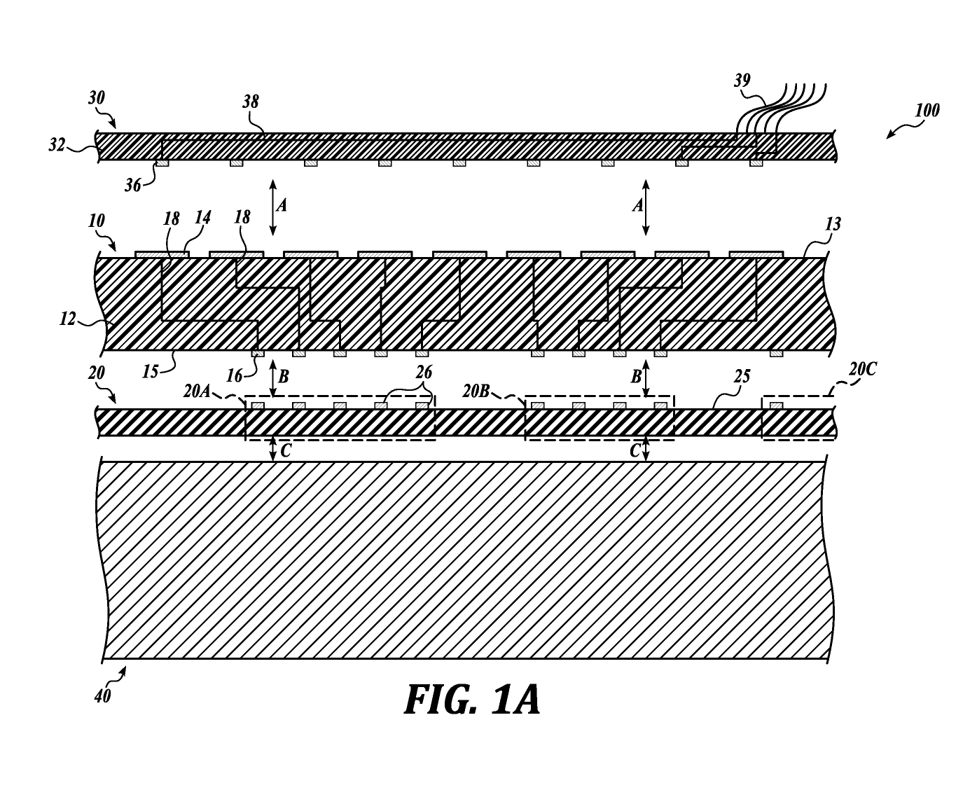

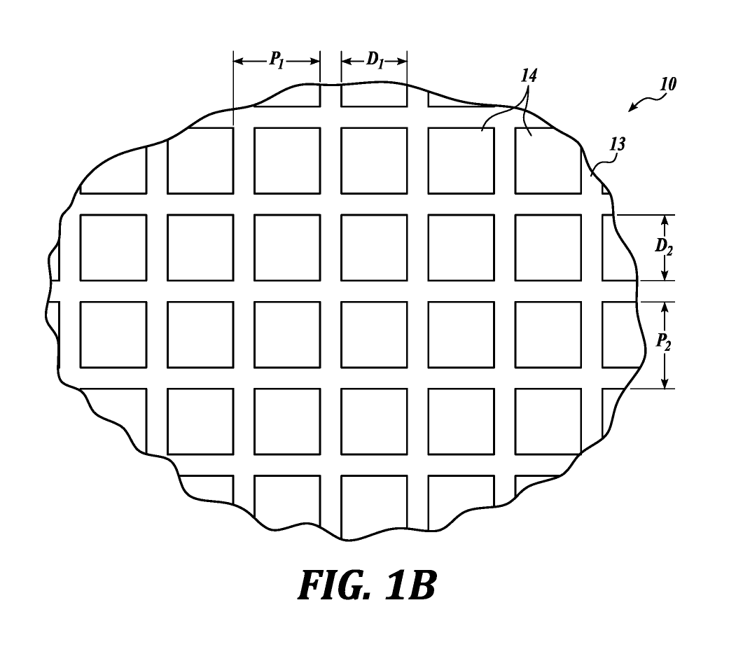

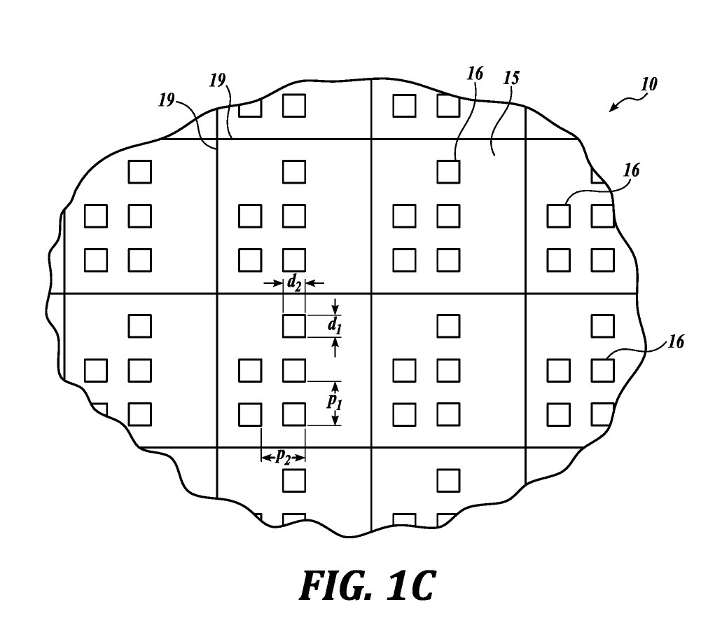

Specific details of several embodiments of representative wafer translators and associated methods for use and manufacture are described below. The wafer translators can be used for testing semiconductor dies on a wafer. The semiconductor dies may include, for example, memory devices, logic devices, light emitting diodes, micro-electro-mechanical-systems, and/or combinations of these devices. A person skilled in the relevant art will also understand that the technology may have additional embodiments, and that the technology may be practiced without several of the details of the embodiments described below with reference to FIGS. 1A-6.

Briefly described, methods and devices for testing dies on the semiconductor wafers are disclosed. The semiconductor wafers are produced in several diameters, e.g., 150 mm, 200 mm, 300 mm, 450 mm, etc. The disclosed methods and systems enable operators to test devices having pads, solderballs and/or other contact structures having small sizes and/or pitches. Solderballs, pads, and/or other suitable conductive elements on the dies are collectively referred to herein as “contact structures” or “contacts.” In many embodiments, the technology described in the context of one or more types of contact structures can also be applied to other contact structures.

In some embodiments, a wafer-side of the wafer translator carries the wafer-side contact structures having relatively small sizes and/or pitches (collectively, “scale”). The wafer-side contact structures of the wafer translator are electrically connected to corresponding inquiry-side contact structures having relatively larger sizes and/or pitches at the opposite, inquiry-side of the wafer translator. Therefore, once the wafer-side contact structures are properly aligned to contact the semiconductor wafers, the larger size/pitch of the opposing inquiry-side contact structures enable more robust contact (e.g., requiring less precision). The larger size/pitch of the inquiry-side contact structures may provide more reliable contact and be easier to align against the pins of the test contactor. In some embodiments, the inquiry-side contacts may have mm scale, while the wafer-side contacts have sub-mm or μm scale.

In at least some embodiments, contact between the wafer translator and the wafer is facilitated by a vacuum in a space between the wafer translator and the wafer. For example, a pressure differential between a lower pressure (e.g., sub-atmospheric pressure) in the space between the wafer translator and the wafer, and a higher outside pressure (e.g., atmospheric pressure) can generate a force over the inquiry-side of the wafer translator resulting in a sufficient electrical contact between the wafer-side contact structures and the corresponding die contacts of the wafer.

Many embodiments of the technology described below may take the form of computer- or controller-executable instructions, including routines executed by a programmable computer or controller. Those skilled in the art will appreciate that the technology can be practiced on computer/controller systems other than those shown and described below. The technology can be embodied in a special-purpose computer, controller or data processor that is specifically programmed, configured or constructed to perform one or more of the computer-executable instructions described below. Accordingly, the terms “computer” and “controller” as generally used herein refer to any data processor and can include Internet appliances and hand-held devices (including palm-top computers, wearable computers, cellular or mobile phones, multi-processor systems, processor-based or programmable consumer electronics, network computers, mini computers and the like). Information handled by these computers can be presented by any suitable display medium, including a CRT display or LCD.

The technology can also be practiced in distributed environments, where tasks or modules are performed by remote processing devices that are linked through a communications network. In a distributed computing environment, program modules or subroutines may be located in local and remote memory storage devices. Aspects of the technology described below may be stored or distributed on computer-readable media, including magnetic or optically readable or removable computer disks, as well as distributed electronically over networks. Data structures and transmissions of data particular to aspects of the technology are also encompassed within the scope of the embodiments of the technology.

FIG. 1A is an exploded view of a portion of a test stack 100 for testing semiconductor wafers in accordance with an embodiment of the presently disclosed technology. The test stack 100 can route signals and power from a tester (not shown) to a wafer or other substrate carrying one or more devices under test (DUTs), and transfer the output signals from the DUTs (e.g., semiconductor dies) back to the tester for analysis and determination about an individual DUT's performance (e.g., whether the DUT is suitable for packaging and shipment to the customer). The DUT can be a single semiconductor die or multiple semiconductor dies (e.g., when using a parallel test approach). The signals and power from the tester may be routed through a test contactor 30 to a wafer translator 10, and further to the semiconductor dies on the wafer 20.

In some embodiments, the signals and power can be routed from the tester to the test contactor 30 using cables 39. Conductive traces 38 carried by a test contactor substrate 32 can electrically connect the cables 39 to contacts 36 on the opposite side of the test contactor substrate 32. In operation, the test contactor 30 can contact an inquiry-side 13 of a wafer translator 10 as indicated by arrows A. In at least some embodiments, relatively large inquiry-side contact structures 14 can improve alignment with the corresponding contacts 36 of the test contactor 30. The contact structures 14 at the inquiry-side 13 are electrically connected with relatively small wafer-side contact structures 16 on a wafer-side 15 of the translator 10 through conductive traces 18 of a wafer translator substrate 12. The size and/or pitch of the wafer-side contact structures 16 are suitable for contacting the corresponding die contacts 26 of the wafer 20. Arrows B indicate a movement of the wafer translator 10 to make contact with an active side 25 of the wafer 20. As explained above, the signals and power from the tester can test the DUTs of the wafer 20, and the output signals from the tested DUTs can be routed back to the tester for analysis and a determination as to whether the DUTs are suitable for packaging and shipment to the customer.

The wafer 20 is supported by a wafer chuck 40. Arrows C indicate the direction of the wafer 20 mating with the wafer chuck 40. In operation, the wafer 20 can be held against the wafer chuck 40 using, e.g., vacuum V or mechanical clamping.

FIGS. 1B and 1C are partially schematic, top and bottom views, respectively, of a wafer translator configured in accordance with embodiments of the presently disclosed technology. FIG. 1B illustrates the inquiry-side 13 of the wafer translator 10. Distances between the adjacent inquiry-side contact structures 14 (e.g., pitch) are denoted P₁ in the horizontal direction and P₂ in the vertical direction. The illustrated inquiry-side contact structures 14 have a width D₁ and a height D₂. Depending upon the embodiment, the inquiry-side contact structures 14 may be squares, rectangles, circles or other shapes. Furthermore, the inquiry-side contact structures 14 can have a uniform pitch (e.g., P₁ and P₂ being equal across the translator 10) or a non-uniform pitch.

FIG. 1C illustrates the wafer-side 15 of the wafer translator 10. In some embodiments, the pitch between the adjacent wafer-side contact structures 16 can be p₁ in the horizontal direction and p₂ in the vertical direction. The width and height of the wafer-side contact structures 16 (“characteristic dimensions”) are denoted as d₁ and d₂. In some embodiments, the wafer-side contact structures 16 can be pins that touch corresponding die contacts on the wafer 30 (FIG. 1A). In general, the size/pitch of the inquiry-side contact structures 14 is larger than the size/pitch of the wafer-side contact structures 16, therefore improving alignment and contact between the test contactor and the wafer translator. The individual dies of the wafer 10 are typically separated from each other by wafer streets 19.

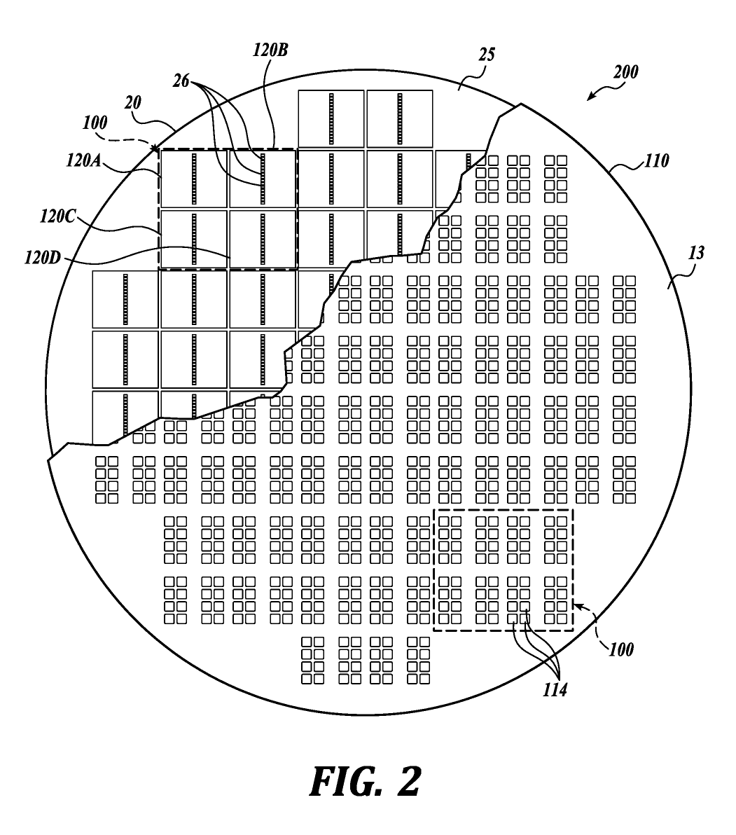

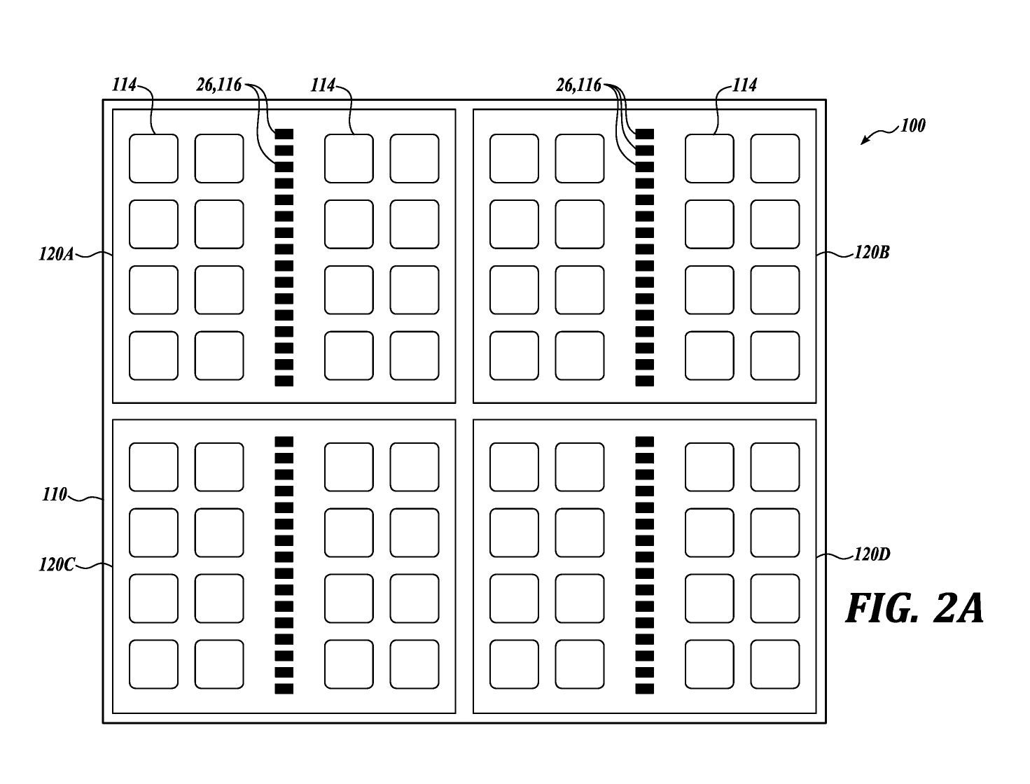

FIG. 2 is a partially schematic top view of an assembly 200 that includes a wafer translator 110 and the wafer 20 in accordance with an embodiment of the presently disclosed technology. The illustrated top view includes the inquiry-side 13 of the wafer translator 110, and the active side 25 of the wafer 20. The wafer translator 110 is illustrated in a partial view with the northwest section of the wafer translator removed to show an unobstructed view of the wafer 20. In some embodiments, the wafer translator 110 and the wafer 20 may be held in electrical contact by a vacuum or by mechanical clamping. In some embodiments, the test contactor 30 (not shown) may contact the inquiry side 13 of the wafer-translator 110 to establish electrical contact between the wafer 20 (i.e., the dies of the wafer) and the tester.

The wafer 20 includes multiple groups of dies 120A-120D shown in a detail 100. In the illustrated embodiment, the die 120A denotes a northeast die in the group, the die 120B denotes the northwest die, the die 120C denotes the southwest die, and the die 120D denotes the southeast die. The individual dies include a group of the die contacts 26 (e.g., a column of the die contacts 26) that may be used for die testing.

The inquiry-side 13 of the wafer translator 110 includes inquiry-side contact structures 114 that, in operation, can be contacted by the contacts of the test contactor 30 (not shown) to transfer test signals/power from the tester to the dies of the wafer 20, and back. As explained with reference to FIGS. 1A-1C, the size/pitch of the inquiry-side contact structures 114 may be relatively large for easier alignment between the wafer translator 110 and the test contactor 30. The wafer-side 15 of the wafer translator 110 carries wafer-side contact structures 116 that can contact the corresponding die contacts 26.

FIG. 2A is a detail view of the detail 100 of the overlay illustrated in FIG. 2. The test stack detail 100 includes four dies (120A-120D) of the wafer 20 and the corresponding portion of the wafer translator 110 that overlays the dies 120A-120D. In the illustrated embodiment, the wafer translator 110 includes the inquiry-side contact structures 114 that are distributed about the wafer-side contact structure 116 at the opposing side of the wafer translator 110. In at least some embodiments, the inquiry-side contact structures 114 can have larger size/pitch than the corresponding wafer-side contact structures 116 that face the die contacts 26. When properly aligned, the wafer-side contact structures 116 can contact the corresponding dies contacts 26 to establish electrical contact.

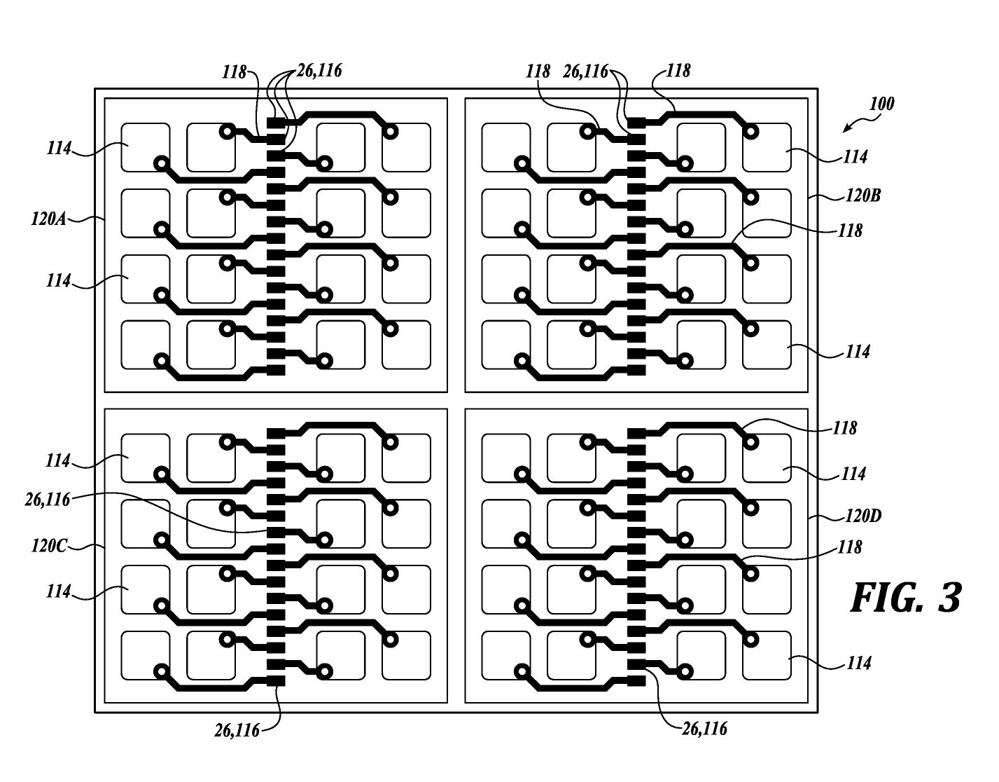

FIG. 3 is a partially schematic view of routing of the wafer translator 10 in accordance with an embodiment of the presently disclosed technology. Conductive traces 118 can route signal/power from the inquiry-side contact structures 114 to the wafer-side contact structures 116. The conductive traces 118 may be routed on a routing layer inside the wafer translator 10. In some embodiments, the conductive traces 118 take a relatively short and direct route from the inquiry-side contact structures 114 to the wafer-side contact structures 116. Therefore, the inquiry-side contact structures 114 are routed to their proximate wafer-side contact structures 116 using relatively short and direct routes. As a result, the inquiry-side contact structures 114 that overlay a particular die (e.g., a die 120A) are also routed to the wafer-side contact structures 116 that contact the die contacts 26 of that particular die (e.g., the die 120A).

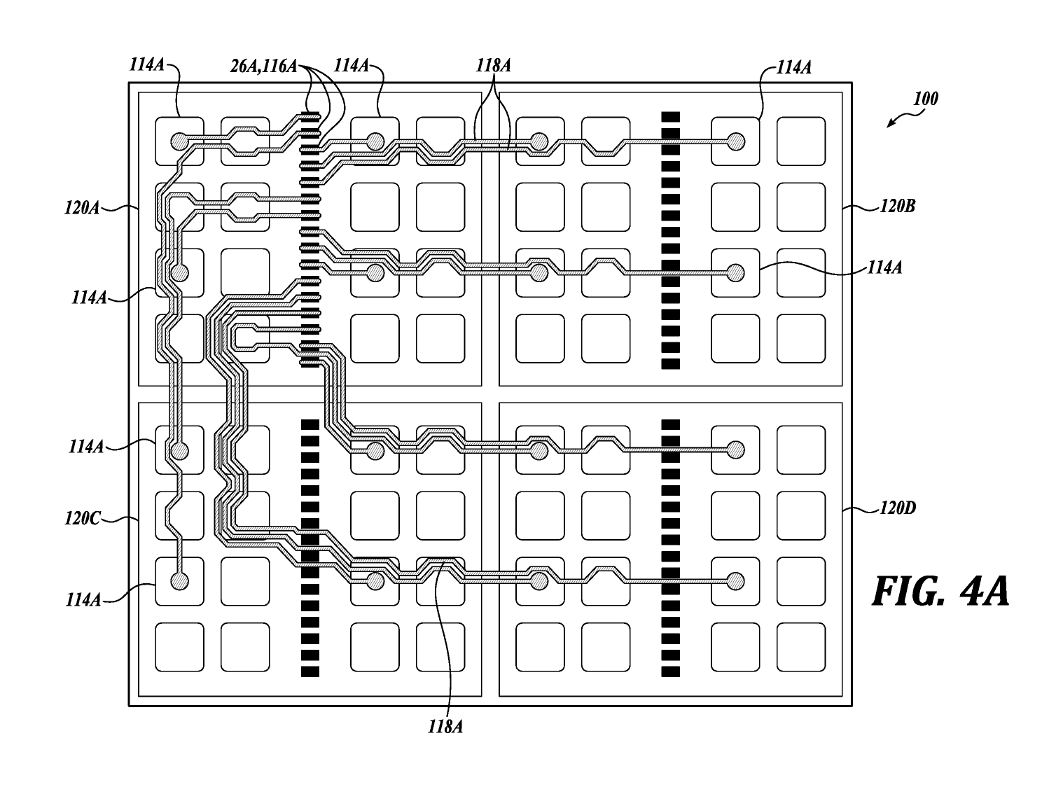

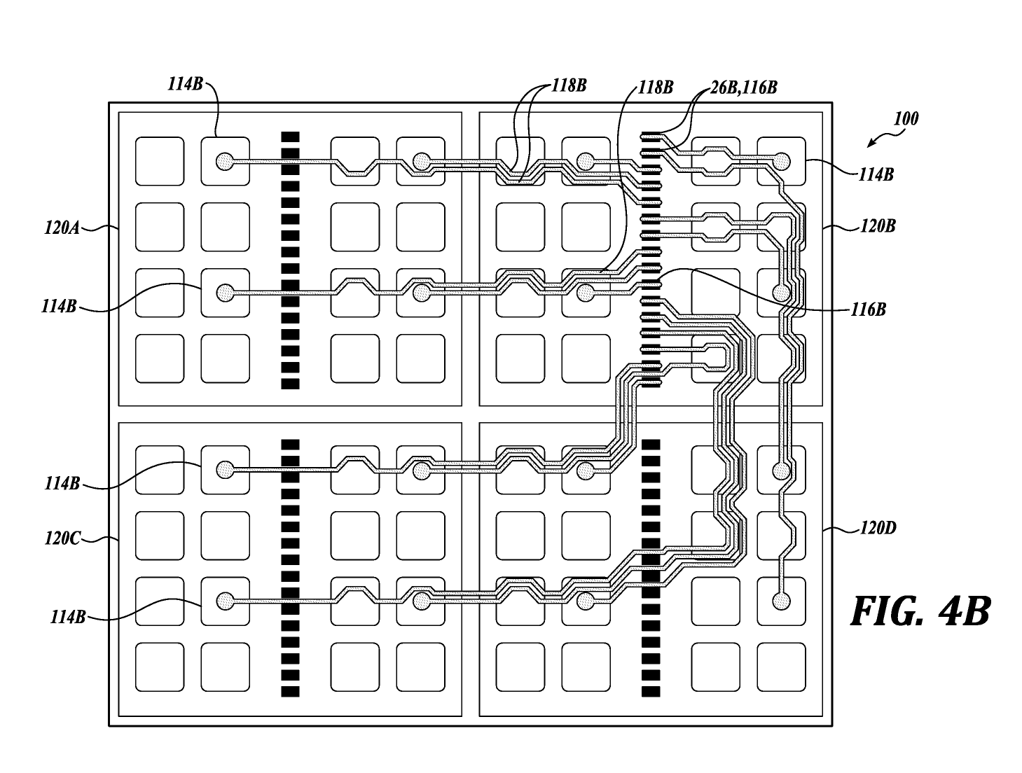

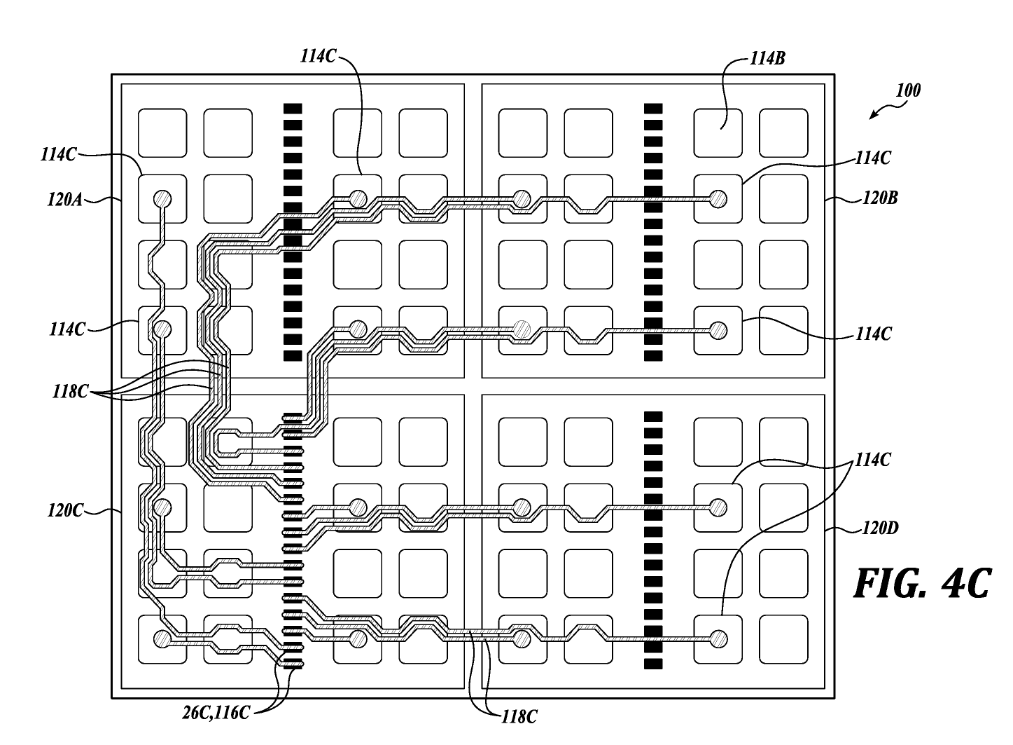

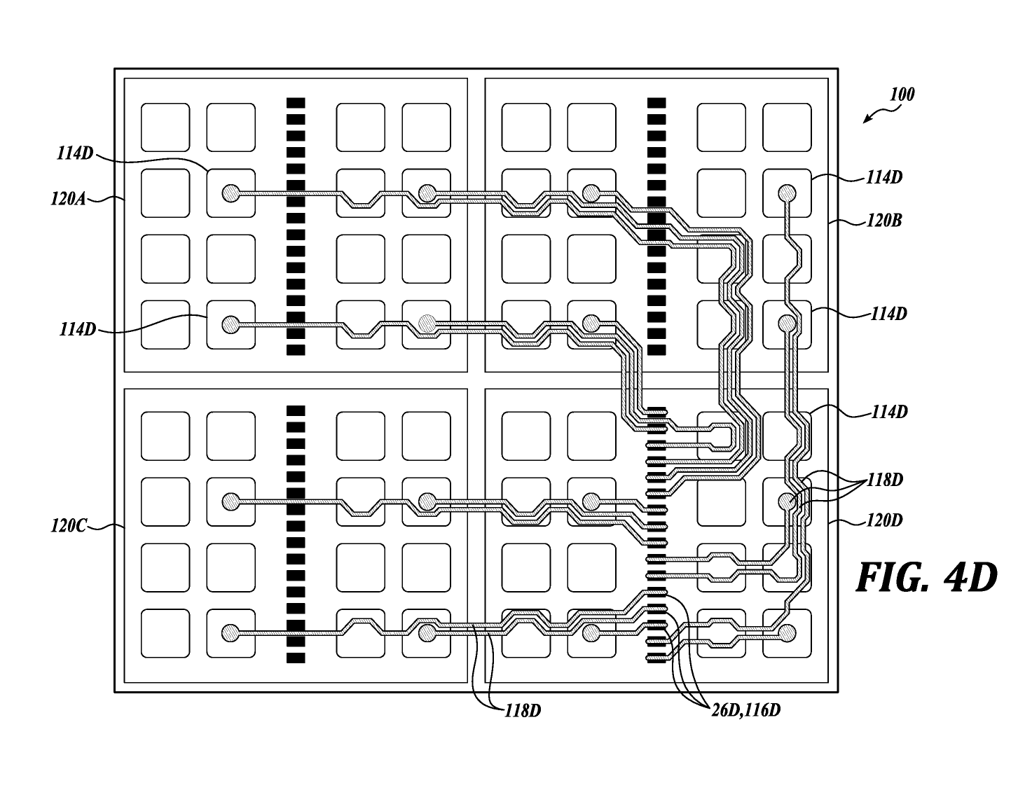

FIGS. 4A-4D are partially schematic views of a wafer translator routing in accordance with an embodiment of the presently disclosed technology. In at least some embodiments, the wafer translator routing illustrated in FIGS. 4A-4D can facilitate testing the dies of the wafer using a reduced number of touch-downs (e.g., four touch-downs) while eliminating or at least minimizing the overhang of the test contactor over the edge of the wafer translator and/or wafer. The pattern illustrated in FIGS. 4A-4D may be repeated over the most of or the entire wafer 20. For better illustration of the routing, the schematic views of FIGS. 4A-4D include the die contacts 116A-116D, the contact structures 116A-116D of the wafer translator, and the conductive traces 118A-118D, which, in at least some embodiments, would not be directly visible in the top view. A person of ordinary skill would understand that the die contacts, the contact structures of the wafer translator, and/or conductive traces may be laid out using engineering software for computer aided design (CAD), for example Allegro by Cadence Design Systems.

FIG. 4A illustrates the routing of the test stack detail 100 of the wafer translator 20 corresponding to the die 120A. In some embodiments, the inquiry-side contact structures 114A of the wafer translator 110 are routed to the wafer-side contact structures 116A of the wafer translator 110 that face the die contacts 26 of the die 120A. As a result, contacting the inquiry-side contact structures 114A with the test contactor 30 can establish electrical contact between the tester and the die(s) 120A to test the die(s) 120A.

FIG. 4B illustrates the routing of the test stack detail 100 of the wafer translator 20 corresponding to the die 120B. In some embodiments, the inquiry-side contact structures 114B may be interleaved with and uniformly offset from the inquiry-side contact structures 114A (e.g., a pattern of the inquiry-side contact structures 114B is offset from the pattern of the inquiry-side contact structures 114B by one inquiry-side contact structure to the right). The illustrated inquiry-side contact structures 114B may be connected with routing traces 118B to the wafer-side contact structures 116B, which correspond to the die contacts 26 of the die 120B. Therefore, in some embodiments, by moving the test contactor 30 by one inquiry-side contact structure to the right (e.g., from contacting the contact structures 114A to contacting the contact structures 114B), the test contactor 30 can terminate electrical contact with the die(s) 120A and establish electrical contact between the tester and the die(s) 120B.

FIG. 4C illustrates the routing of the test stack detail 100 of the wafer translator 20 corresponding to the die 120C. In the illustrated embodiment, the inquiry-side contact structures 114C are interleaved with and uniformly offset by one inquiry-side contact structure down from the contact structures 114A (i.e., diagonally down from the contact structures 114B). The inquiry-side contact structures 114C may be connected with routing traces 118C to the wafer-side contact structures 116C, which correspond to the die contacts 26 of the die 120C. Therefore, in some embodiments, by moving the test contactor 30 by one inquiry-side contact structure down (e.g., from contacting the contact structures 114A to contacting the contact structures 114C) or diagonally down (e.g., from contacting the contact structures 114B to contacting the contact structures 114C), the test contactor 30 can establish electrical contact between the tester and the die(s) 120C.

FIG. 4D illustrates the routing of the test stack detail 100 of the wafer translator 20 corresponding to the die 120D. In the illustrated embodiment, the inquiry-side contact structures 114D are offset relative to the inquiry-side contact structures by one inquiry-side contact structure (e.g, diagonally down from the contact structures 114A, or to the right from the contact structures 114C, or down from the contact structures 114B). Therefore, in some embodiments, by repositioning the test contactor 30 by one inquiry-side contact structure down (i.e., from contacting the contact structures 114A to contacting the contact structures 114D) or repositioning the test contactor 30 analogously with respect to the contact structures 114B and 114C, the test contactor 30 can establish electrical contact between the tester and the die(s) 120D. For example, the inquiry-side contact structures 114D may be connected with routing traces 118D to the wafer-side contact structures 116D, which correspond to the die contacts 26 of the die 120D.

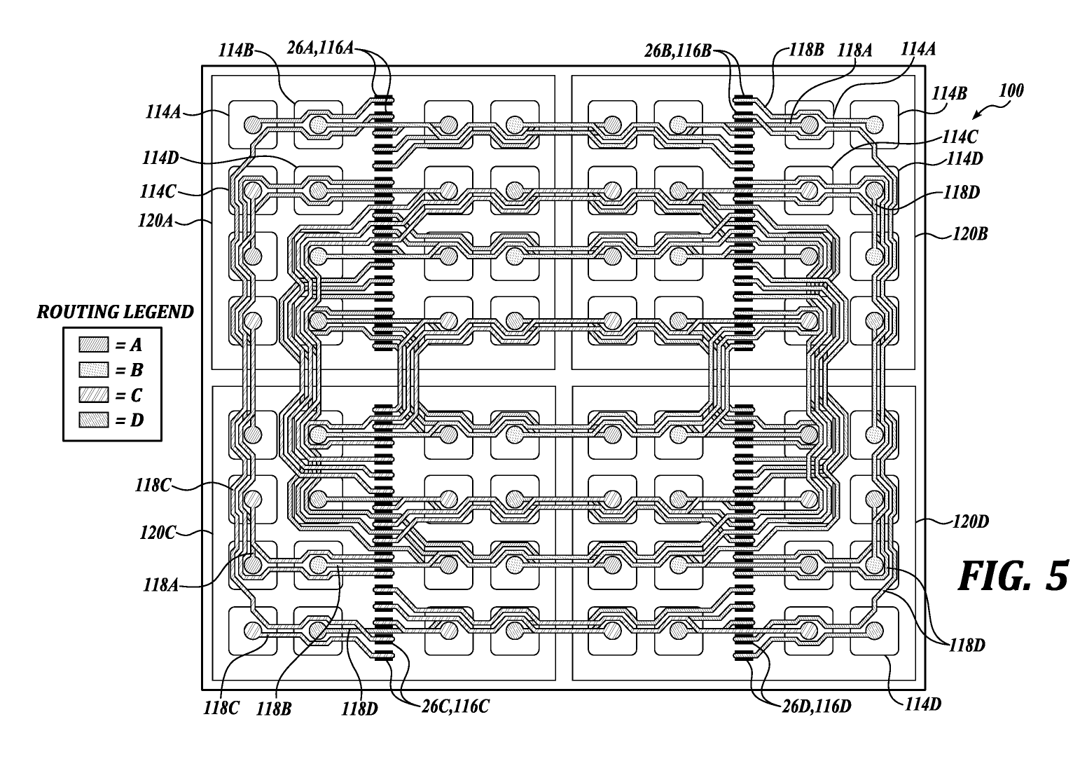

FIG. 5 is a partially schematic view of a wafer translator routing in accordance with an embodiment of the presently disclosed technology. FIG. 5 illustrates the routing traces that combine the routing illustrated in FIGS. 4A-4D. The Routing Legend denotes the contact structures and the routing traces (A, B, C, D) of the wafer translator 10 that can connect the test contactor 30 with the inquiry-side of the wafer translator 110, and further with the corresponding dies 120A-120D. In the illustrated embodiment, the inquiry-side contact structures 114A-114D are interleaved such that, for example, each inquiry-side contact structure 114A is adjacent to a corresponding inquiry-side contact structure 114B. In other embodiments, the inquiry-side contact structures may be interleaved by a distance of two or more individual inquiry-side contact structure. The routing from the inquiry-side contact structures 114A-114D to the wafer-side contact structures 116A-116D is sometimes called interdigitized polysymmetric fanout.

In at least some embodiments, by stepping the test contactor 30 by one inquiry-side contact, for example, from contacting the inquiry-side contacts 114B to contacting the inquiry-side contacts 114C, the tester terminates electrical contact with the dies 120B, and establishes electrical contact with the dies 120C. The process may continue by stepping the test contactor 30 by one inquiry-side contact from the inquiry-side contacts 114C to the inquiry-side contacts 114A, etc. In some embodiments, for example, when the pattern of four dies 120A-120D repeats across the semiconductor wafer 20, the test contactor 30 may establish electrical contact with all or almost all dies with four touch-downs of the test contactor 30 against the wafer translator 10. In at least some embodiments, this sequence of touch-downs between the test contactor 30 and the wafer translator 20 can reduce or eliminate an overhang of the test contactor 30 over the edge of the semiconductor wafer 20 and/or the wafer translator 10. In some embodiments, all the dies 120A may be tested in parallel at a touch-down of the test contactor 30, followed by testing all the dies 120B in parallel with the next touch-down, etc.

In some embodiments, the wafer translator 10 may include multiple routing layers for routing the conductive traces 118A-118D. For example, each group of conductive traces 118A-118D may be routed in a dedicated routing layer of a four-layer wafer translator 110. Other routing approaches are possible, for example, using one routing layer for two groups of conductive traces resulting in a two-layer wafer translator 10 (e.g., the conductive traces 118A and 118C in one routing layer, and the conductive traces 118B and 118D in another routing layer). Other distributions of the conductive traces within the routing layers are possible.

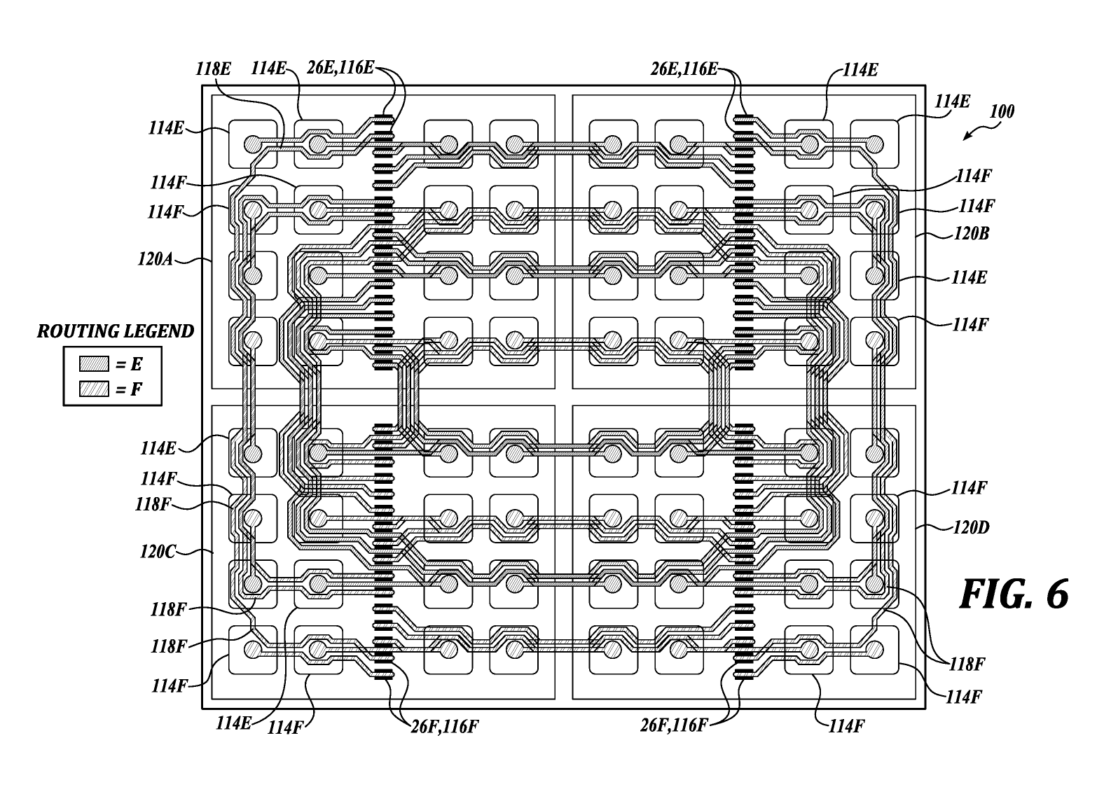

FIG. 6 is a partially schematic view of a wafer translator routing in accordance with another embodiment of the presently disclosed technology. The illustrated test stack detail 100 includes a portion of the wafer translator 110 that overlays the four dies 120A-120D. In the illustrated embodiment, the inquiry-side contact structures 114E and 114F of the wafer translator 110 are routed to the wafer-side contact structures 116E and 116F, respectively. The Routing Legend denotes the contact structures and the routing traces (E, F) that can connect the test contactor 30 with the corresponding dies 120A-120D. In the illustrated embodiment, the test contactor 30 can establish electrical contact with all or all almost all dies on the wafer with just two touch-downs of the test contactor 30 over the wafer translator 10. For example, the test contactor may contact the inquiry-side contact structures the inquiry-side contact structures 114E to establish electrical contact with the dies 120A and 120B of the group of 4 dies 120A-120D. In some embodiments, after testing the dies 120A and 120B, the test contactor 30 may be repositioned into a contact with the inquiry-side contact structures 114F to establish electrical contact with the dies 120C and 120D by, for example, stepping the test contactor 30 by one inquiry-side contact structure down (e.g., from the inquiry-side contact structures 114E to the inquiry-side contact structures 114F). Other groups of four dies on the semiconductor wafer (shown in FIG. 2) can also have two dies (e.g., dies 120A/120B, or dies 120C/120D) in electrical contact with the test contactor 30 per touch down. In some embodiments, all or almost all dies on the semiconductor wafer may be tested by this sequence of touch-downs while eliminating or at least reducing an overhang of the test contactor 30 over the edge of the semiconductor wafer 20 and the wafer translator 10. In some embodiments, the conductive traces 118E, 118F may be routed in multiple routing layers (e.g., three or four routing layers) of the wafer translator 10 to reduce routing trace congestion.

From the foregoing, it will be appreciated that specific embodiments of the technology have been described herein for purposes of illustration, but that various modifications may be made without deviating from the disclosure. For example, in some embodiments, testing of the dies may be done using the tester resources (e.g., tester chips that generate test vectors) carried by the wafer translator, or the tester resources can be carried partially by the tester and partially by the wafer translator. Moreover, while various advantages and features associated with certain embodiments have been described above in the context of those embodiments, other embodiments may also exhibit such advantages and/or features, and not all embodiments need necessarily exhibit such advantages and/or features to fall within the scope of the technology. Accordingly, the disclosure can encompass other embodiments not expressly shown or described herein.

The embodiments of the invention in which an exclusive property or privilege is claimed are defined as follows:

1. An apparatus for testing semiconductor dies, comprising:
a wafer translator having
a wafer-side facing the dies, wherein the wafer-side of the wafer translator carries a first and a second plurality of wafer-side contact structures, wherein the first plurality of the wafer-side contact structures is configured to face die contacts of a first die, and wherein the second plurality of the wafer-side contact structures is configured to face the die contacts of a second die;
an inquiry-side facing away from the wafer-side, wherein the inquiry-side of the wafer translator carries a first and a second plurality of inquiry-side contact structures; and
conductive traces connecting the first plurality of the wafer-side contact structures with the first plurality of inquiry-side contact structures, and the second plurality of the wafer-side contact structures with the second plurality of inquiry-side contact structures,
wherein the first plurality of the inquiry-side contact structures is interleaved with the second plurality of the inquiry-side contact structures.

2. The apparatus of claim 1 wherein the wafer-side contact structures have a first scale, wherein the inquiry-side contact structures have a second scale, and wherein the first scale is smaller than the second scale.

3. The apparatus of claim 1 wherein the inquiry-side contact structures of the first plurality of the wafer-side contact structures are arranged in a first pattern, the inquiry-side contact structures of the second plurality of the wafer-side contact structures are arranged in a second pattern, and wherein the first pattern and the second pattern are the same.

4. The apparatus of claim 1 wherein the first plurality of the inquiry-side contact structures comprises a first pattern, and the second plurality of the inquiry-side contact structures comprises a second pattern, and wherein the first pattern is offset from the second pattern by one inquiry-side contact structure.

5. The apparatus of claim 1 wherein the first plurality of the inquiry-side contact structures comprises a first pattern, and the second plurality of the inquiry-side contact structures comprises a second pattern, and wherein the first pattern is offset from the second pattern by two inquiry-side contact structures.

6. The apparatus of claim 1 wherein the inquiry-side contact structures of the first plurality of the wafer-side contact structures are arranged in a first pattern, the inquiry-side contact structures of the second plurality of the wafer-side contact structures are arranged in a second pattern, and wherein the first pattern and the second pattern are same.

7. The apparatus of claim 1, further comprising:
a third plurality of wafer-side contact structures; and
a third plurality of inquiry-side contact structures connected with the conductive traces to the third plurality of wafer-side contact structures, wherein the inquiry-side contact structures of the third plurality of the wafer-side contact structures are interleaved with the first and the second pluralities of the wafer-side contact structures.

8. The apparatus of claim 1 wherein the dies are carried by a semiconductor wafer in contact with the wafer translator.

9. The apparatus of claim 1, further comprising a test contactor configured to contact at least one plurality of inquiry-side contact structures.

10. The apparatus of claim 9, further comprising a tester in electrical contact with the test contactor.

11. The apparatus of claim 1 wherein the conductive traces connecting the first plurality of the wafer-side contact structures with the first plurality of inquiry-side contact structures are routed in a first routing layer of the wafer translator, and the conductive traces connecting the second plurality of the wafer-side contact structures with the second plurality of inquiry-side contact structures are routed in a second routing layer of the wafer translator.

12. A method for testing semiconductor dies, comprising:
contacting the semiconductor dies on a semiconductor wafer with wafer-side contact structures of a wafer-side of the wafer translator;
contacting a first plurality of inquiry-side contact structures of an inquiry-side of the wafer translator with a test contactor, wherein the inquiry-side of the wafer translator is opposite the wafer-side of the wafer-translator, and wherein the first plurality of the inquiry-side contact structures is electrically connected to a first die on the semiconductor wafer; and
contacting a second plurality of the inquiry-side contact structures with the test contactor, wherein the second plurality of the inquiry-side contact structures is electrically connected to a second die on the semiconductor wafer, and wherein the first plurality of the inquiry-side contact structures is interleaved with the second plurality of the inquiry-side contact structures.

13. The method of claim 12, further comprising transferring test signals from a tester to the first die and to the second die.

14. The method of claim 12 wherein each die of the semiconductor wafer is electrically connected to the test contactor at least once by contacting the first plurality of inquiry-side contacts and the second plurality of the inquiry-side contact structures.

15. The method of claim 12 wherein each die of the semiconductor wafer is electrically connected to the test contactor at least once by contacting the wafer translator four times.

16. The method of claim 12 wherein the wafer-side contact structures have a first scale, wherein the inquiry-side contact structures have a second scale, and wherein the first scale is smaller than the second scale.

17. The method of claim 12 wherein the first plurality of the inquiry-side contact structures comprises a first pattern, and the second plurality of the inquiry-side contact structures comprises a second pattern, and wherein the first pattern is offset from the second pattern by one inquiry-side contact structure.

18. The method of claim 12 wherein the inquiry-side contact structures of the first plurality of the wafer-side contact structures are arranged in a first pattern, the inquiry-side contact structures of the second plurality of the wafer-side contact structures are arranged in a second pattern, and wherein the first pattern and the second pattern are same.
